(19) United States
(12) Patent Application Publication
(10) Pub. No.: US 2025/0072083 A1
(43) Pub. Date: Feb. 27, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Eiko OTSUKI, Tokyo (JP); Yasuhiro YOSHIURA, Fukuoka (JP)

(73) Assignee: Mitsubishi Electric Corporation, Tokyo (JP)

(21) Appl. No.: 18/664,556

(22) Filed: May 15, 2024

(30) Foreign Application Priority Data
Aug. 22, 2023 (JP) 2023-134448

(51) Int. Cl. H01L 29/40; H01L 29/66; H01L 29/739; H01L 29/861

(52) U.S. Cl. CPC H01L 29/404; H01L 29/66325; H01L 29/7393; H01L 29/861

(57) ABSTRACT

An object of the present disclosure is to suppress corrosion of metal used in a termination structure in a semiconductor device. A semiconductor substrate includes a plurality of first termination semiconductor layers of a first conductivity type provided in a first termination region, and a second termination semiconductor layer of a second conductivity type provided in a second termination region. A semiconductor device includes a first insulating layer provided in the first termination region, a plurality of first termination electrode layers electrically connected to the plurality of first termination semiconductor layers, a second termination electrode layer electrically connected to the second termination semiconductor layer, and a second insulating layer contacting with an outermost first termination semiconductor layers and the second termination semiconductor layer.

### BACKGROUND OF THE INVENTION

### Field of the Invention

The present disclosure relates to a semiconductor device.

### Description of the Background Art

In semiconductor devices, a Resistive Field Plate (RFP) is sometimes used to increase the breakdown voltage of the termination region. The RFP promotes the expansion of the depletion layer at the edge of the pn junction located in the termination region and alleviates electric field concentration. This can prevent edge breakdown of the pn junction (see, for example, Japanese Patent Application Laid-Open No. 2020-150025).

In recent years, with the aim of carbon emission reduction and energy saving, the applications of semiconductor products such as power modules have been diversifying, and there is a demand for high reliability in various environmental conditions that meet user requirements. In particular, the required levels tend to be higher in the Temperature Humidity Bias (THB) test. In the THB test, there is a problem in that the metal used in the termination structure corrodes, resulting in a break or an increase in breakdown voltage leakage.

### SUMMARY

An object of the present disclosure is to suppress corrosion of metal used in a termination structure in a semiconductor device.

A semiconductor device of the present disclosure includes a semiconductor substrate. The semiconductor device is divided into an active region, a first termination region surrounding the active region, and a second termination region surrounding the first termination region in a plan view. The semiconductor substrate has a first main surface and a second main surface, which is a main surface on the opposite side to the first main surface. The semiconductor substrate includes a drift layer of a second conductivity type, a plurality of first termination semiconductor layers of a first conductivity type, and a second termination semiconductor layer of the second conductivity type. The plurality of first termination semiconductor layers are provided in the front surface layer of the drift layer on the first main surface side in the first termination region. The second termination semiconductor layer is provided in the front surface layer of the drift layer on the first main surface side at an end portion of the semiconductor substrate in the second termination region. The semiconductor device includes a first insulating layer, a plurality of first termination electrode layers, a second termination electrode layer, a second insulating layer, and a sealing material. The first insulating layer is provided on the first main surface in the first termination region. A plurality of the first termination electrode layers are electrically contacted to the plurality of first termination semiconductor layers through openings of the first insulating layer. The second termination electrode layer is provided on the first main surface and electrically connected to the second termination semiconductor layer. The second insulating layer is provided on the first main surface and has one end in contact with the outermost one of the plurality of first termination semiconductor layers among the plurality of first termination semiconductor layers, and the other end in contact with the second termination semiconductor layer. The sealing material is in direct contact with the upper surface of the second insulating layer.

According to the semiconductor device of the present disclosure, the sealing material is in direct contact with the upper surface of the second insulating layer. Therefore, ions generated in the outermost first termination semiconductor layer or the second termination semiconductor layer during the THB test are dispersed in the sealing material as they move on the upper surface of the second insulating layer. Therefore, corrosion of the metal used for the first termination electrode layers or the second termination electrode layer is suppressed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view illustrating a configuration of a semiconductor device according to Embodiment 1;

FIG. 2 is a cross-sectional view illustrating the configuration of the semiconductor device according to Embodiment 1;

FIG. 3 is a top view illustrating a configuration of a semiconductor device according to Embodiment 2;

FIG. 4 is a cross-sectional view illustrating the configuration of the semiconductor device according to Embodiment 2;

FIG. 5 is a cross-sectional view of a main part of the semiconductor device according to Embodiment 2, illustrating a second insulating layer where a non-reference plane is formed as a concave portion;

FIG. 6 is a cross-sectional view of a main part of the semiconductor device according to Embodiment 2, illustrating the second insulating layer in which portions of the non-reference planes formed as convex portions are under a first termination electrode layer and a second termination electrode layer;

FIG. 7 is a cross-sectional view illustrating the second insulating layer of which the non-reference planes have a triangular cross section;

FIG. 8 is a cross-sectional view illustrating the second insulating layer of which the non-reference planes have a tapered shape;

FIG. 9 is a cross-sectional view illustrating the second insulating layer of which the non-reference planes are a curved surface;

FIG. 10 is a cross-sectional view illustrating the second insulating layer of which the non-reference planes are formed of both convex portions and concave portions;

FIG. 11 is an enlarged view of a region B in FIG. 3 when a concave-convex pattern on the upper surface of the second insulating layer is a stripe pattern;

FIG. 12 is an enlarged view of the region B in FIG. 3 when the concave-convex pattern on the upper surface of the second insulating layer is a discontinuous stripe pattern;

FIG. 13 is an enlarged view of a region B in FIG. 3 when the concave-convex pattern on the upper surface of the second insulating layer is a checkered pattern;

FIG. 14 is an enlarged view of a region B in FIG. 3 when the concave-convex pattern on the upper surface of the second insulating layer is a dot pattern;

FIG. 15 is a top view illustrating a configuration of the semiconductor device according to Embodiment 2 where concave-convex regions of the second insulating layer are provided only at the chip corners;

FIG. 16 is a top view illustrating a configuration of the semiconductor device according to Embodiment 2 where the density of the concave-convex pattern of the second insulating layer at the chip corners is higher than the density of the concave-convex pattern of the second insulating layer in other regions;

FIG. 17 is a cross-sectional view illustrating a manufacturing process of the semiconductor device according to Embodiment 2;

FIG. 18 is a cross-sectional view illustrating a manufacturing process of the semiconductor device according to Embodiment 2;

FIG. 19 is a cross-sectional view illustrating a manufacturing process of the semiconductor device according to Embodiment 2;

FIG. 20 is a cross-sectional view illustrating a manufacturing process of the semiconductor device according to Embodiment 2;

FIG. 21 is a cross-sectional view illustrating a manufacturing process of the semiconductor device according to Embodiment 2;

FIG. 22 is a cross-sectional view of a main part of the semiconductor device according to Embodiment 3; and

FIG. 23 is a cross-sectional view of a semiconductor device according to Embodiment 4.

### DESCRIPTION OF THE PREFERRED EMBODIMENTS

In the following description, the conductivity type of a semiconductor will be described as a first conductivity type or a second conductivity type. For example, the first conductivity type is n-type and the second conductivity type is p-type. Alternatively, p-type may be the first conductivity type and n-type may be the second conductivity type.

### A. Embodiment 1

### <A-1. Configuration>

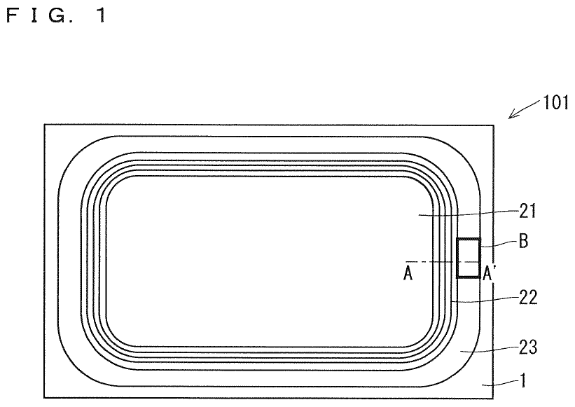

FIG. 1 is a top view of a semiconductor device 101 according to Embodiment 1. As illustrated in FIG. 1, in plan view, the semiconductor device 101 is divided into an active region 21 in the center thereof, a first termination region 22 surrounding the active 25 region 21, and a second termination region 23 surrounding the first termination region 22.

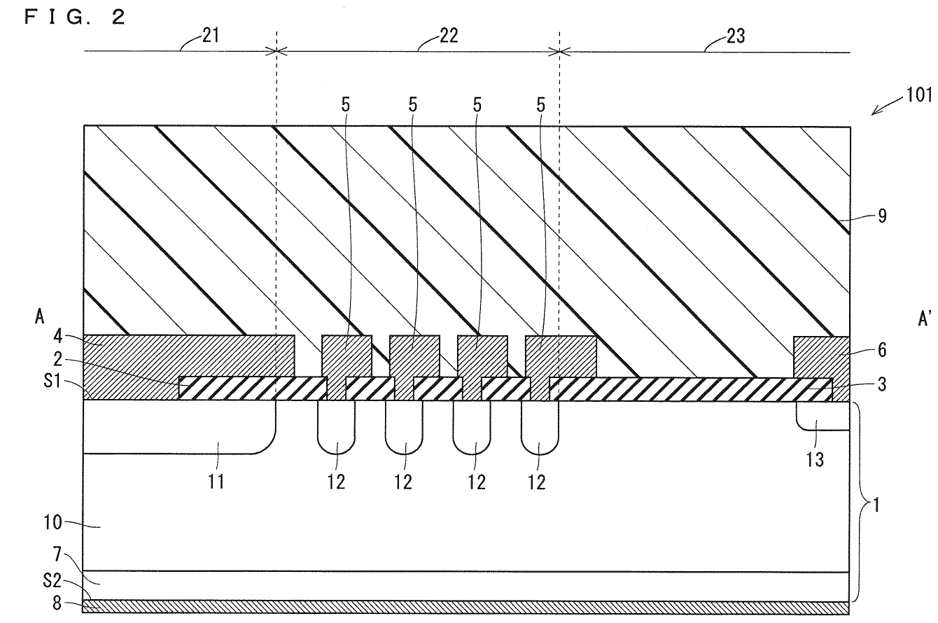

FIG. 2 is a cross-sectional view of the semiconductor device 101 taken along line A-A′ in FIG. 1. The semiconductor device 101 includes a semiconductor substrate 1, a first insulating layer 2, a second insulating layer 3, an active region electrode layer 4, a first termination electrode layer 5, a second termination electrode layer 6, a back surface electrode 8, and a sealing material 9.

The semiconductor substrate 1 has a first main surface S1 and a second main surface S2, which is a main surface on the opposite side to the first main surface S1. The semiconductor substrate 1 is a substrate composed of silicon, silicon carbide, gallium nitride, or the like and has a thickness of 50 μm to several hundred μm. The semiconductor substrate 1 includes a drift layer 10, an active region semiconductor layer 11, a first termination semiconductor layer 12, a second termination semiconductor layer 13, and a buffer layer 7.

The semiconductor substrate 1 includes the drift layer 10 of a second conductivity type. In the front surface layer of the drift layer 10 on the first main surface S1 side, the active region semiconductor layer 11 of a first conductivity type, a plurality of first termination semiconductor layers 12 of the first conductivity type, and a second termination semiconductor layer 13 of the second conductivity type are formed locally. The active region semiconductor layer 11 is formed in the active region 21, the plurality of first termination semiconductor layers 12 are formed in the first termination region 22, and the second termination semiconductor layer 13 is formed in the second termination region 23 at the end portion of the semiconductor substrate 1. The plurality of first termination semiconductor layers 12 concentrically surround the active region semiconductor layer 11. The active region semiconductor layer 11 and the plurality of first termination semiconductor layers 12 control the extension of the depletion layer from the center to the end portion of the semiconductor device 101, thereby contributing to maintaining the breakdown voltage. The second termination semiconductor layer 13 is provided by ion implantation or the like.

On the first main surface S1 of the semiconductor substrate 1, the first insulating layer 2 and the second insulating layer 3 are provided. The first insulating layer 2 is provided in the active region 21 and the first termination region 22. The second insulating layer 3 is provided in the second termination region 23. The second insulating layer 3 has one end in contact with the outermost first termination semiconductor layer 12, and the other end in contact with the second termination semiconductor layer 13. The first insulating layer 2 has openings above the first termination semiconductor layers 12.

The active region electrode layer 4 is an electrode provided on the first main surface S1 of the semiconductor substrate 1 in the active region 21, and through which the main current of the semiconductor device 101 flows. The active region electrode layer 4 contacts the active region semiconductor layer 11 through the openings in the first insulating layer 2. In the semiconductor substrate 1 in the active region 21 in contact with the active region electrode layer 4, an Insulated Gate Bipolar Transistor (IGBT) or a diode may be provided.

The plurality of first termination electrode layers 5 are provided on the first main surface S1 of the semiconductor substrate 1 in the first termination region 22, and are separated from the active region electrode layer 4. Each of the first termination electrode layers 5 is electrically isolated. Each of the first termination electrode layers 5 contacts the corresponding first termination semiconductor layers 12 through the opening in the first insulating layer 2. The plurality of first termination electrode layers 5 are field plates that contribute to maintaining the breakdown voltage of the semiconductor device 101.

The second termination electrode layer 6 is provided, in the second termination region 23, on the first main surface S1 of the semiconductor substrate 1, separately from the active region electrode layer 4 and the first termination electrode layers 5. The second insulating layer 3 is provided between the outermost first termination electrode layer 5 and the second termination electrode layer 6. One end of the second insulating layer 3 contacts the outermost first termination electrode layer 5, and the other end contacts the second termination electrode layer 6. The second termination electrode layer 6 is electrically connected to the first termination semiconductor layers 12. The plurality of first termination electrode layers 5 and the second termination electrode layer 6 are made of metal such as A1.

The buffer layer 7 of the second conductivity type is provided in the front surface layer of the semiconductor substrate 1 on the second main surface S2 side. The front surface of the buffer layer 7 constitutes the second main surface S2. On the second main surface S2 of the semiconductor substrate 1, a back surface electrode 8 is provided. Note that a semiconductor layer of the first conductivity type or a semiconductor layer of the second conductivity type may be provided between the buffer layer 7 and the back surface electrode 8. For example, when the semiconductor device 101 is an IGBT, a collector layer of the first conductivity type is arranged between the buffer layer 7 and the back surface electrode 8. Also, when the semiconductor device 101 is a diode, a cathode layer of the second conductivity type is arranged between the buffer layer 7 and the back surface electrode 8.

The upper surfaces of the active region electrode layer 4, the first termination electrode layers 5, the second termination electrode layer 6, the first insulating layer 2, and the second insulating layer 3 are in direct contact with the sealing material 9. The sealing material 9 is made of, for example, an insulating material such as silicone gel or epoxy resin.

### <A-2. Effect>

The semiconductor device 101 according to Embodiment 1 is divided into, in plan view, the active region 21, the first termination region 22 surrounding the active region 21, and the second termination region 23 surrounding the first termination region 22. The semiconductor device 101 has the first main surface S1 and the second main surface S2, which is a main surface on the opposite side to the first main surface S1. The semiconductor substrate 1 includes the drift layer 10 of a second conductivity type, the plurality of first termination semiconductor layers 12 of a first conductivity type provided in the front surface layer of the drift layer 10 on the first main surface S1 side in the first termination region 22, and the second termination semiconductor layer 13 of the second conductivity type provided in the surface layer of the drift layer 10 on the first main surface S1 side at the end portion of the semiconductor substrate 1 in the second termination region 23. The semiconductor device 101 includes the first insulating layer 2 provided on the first main surface S1 in the first termination region 22, the plurality of first termination electrode layers 5 provided on the first main surface S1 and electrically connected to the plurality of first termination semiconductor layers 12 through the openings of the first insulating layer 2, the second termination electrode layer 6 provided on the first main surface S1 and in contact with the second termination semiconductor layer 13, the second insulating layer 3 provided on the first main surface S1, having one end thereof in contact with the outermost first termination semiconductor layer 12 among the plurality of first termination semiconductor layers 12, and having the other end thereof in contact with the second termination semiconductor layer 13, and the sealing material 9 in direct contact with the upper surface of the second insulating layer 3.

With the above configuration, ions generated in the outermost first termination electrode layer 5 or the second termination electrode layer 6 are dispersed in the sealing material 9 as they move on the front surface of the second insulating layer 3. Therefore, corrosion of the metal used for the first termination electrode layers 5 or the second termination electrode layer 6 is suppressed. Further, the process of forming a protective film between the second insulating layer 3 and the sealing material 9 is not required, reducing manufacturing costs.

### B. Embodiment 2

### <B-1. Configuration>

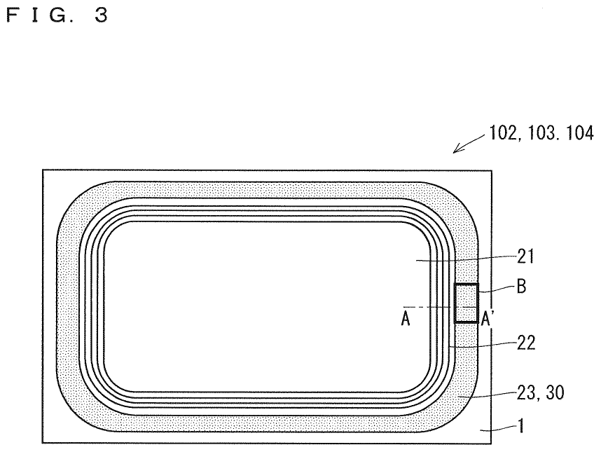

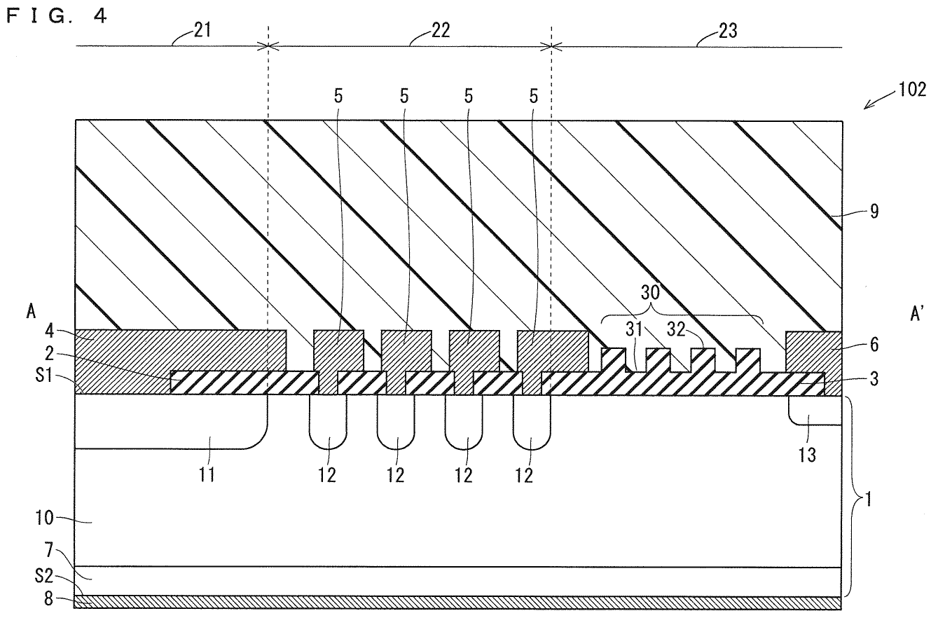

FIG. 3 is a top view of a semiconductor device 102 according to Embodiment 2. FIG. 4 is a cross-sectional view of the semiconductor device 102 taken along line A-A′ in FIG. 3. The semiconductor device 102 differs from the semiconductor device 101 according to Embodiment 1 in that the upper surface of the second insulating layer 3 has a concave-convex region 30 having a concave-convex shape. In FIG. 3, the concave-convex region 30 is subjected to matte hatching.

Specifically, the upper surface of the second insulating layer 3 includes a reference plane 31 having the same height as the upper surface of the first insulating layer 2, and a non-reference plane 32 formed as a convex portion protruding from the reference plane 31. The upper surface of the second insulating layer 3 has a concave-convex shape with the reference plane 31 and the non-reference planes 32. A region of the upper surface of the second insulating layer 3 where the concave-convex shape is provided is referred to as the concave-convex region 30. Note that the second insulating layer 3 needs to have a thickness sufficient to maintain insulation from the semiconductor substrate 1 at the reference plane 31.

As illustrated in FIG. 3, the concave-convex region 30 exists over the entire second termination region 23 so as to surround the first termination region 22.

### <B-2. Concave-Convex Shape of Second Insulating Layer>

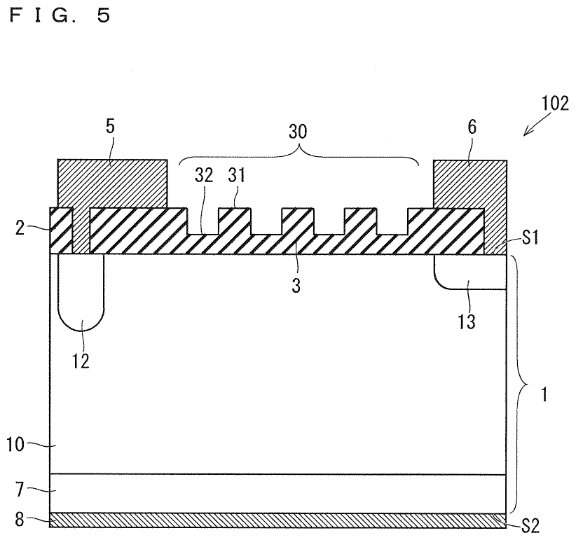

Various shapes are assumed for the concave-convex shape of the second insulating layer 3. In FIG. 4, the non-reference planes 32 are formed as convex portions protruding from the reference plane 31. Alternatively, as illustrated in FIG. 5, the non-reference planes 32 may be formed as concave portions depressed from the reference plane 31. In this case, the second insulating layer 3 needs to have a thickness sufficient to maintain insulation from the semiconductor substrate 1 at the non-reference planes 32.

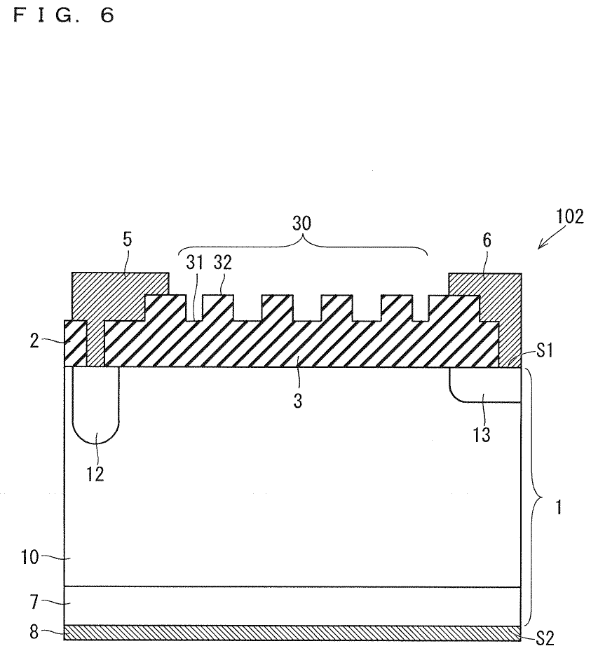

In the case of the non-reference planes 32 being formed as a convex portion protruding from the reference plane 31, the convex portions located at both ends of the second insulating layer 3 may be under the outermost first termination electrode layer 5 and the second termination electrode layer 6, as illustrated in FIG. 6.

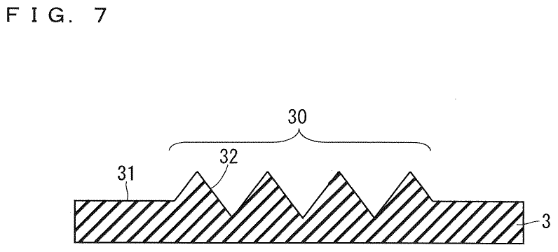

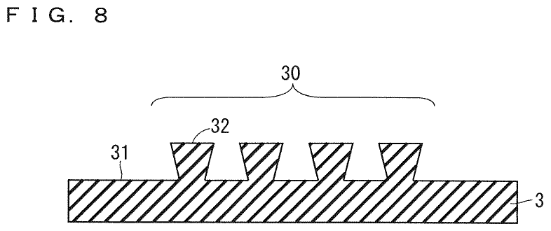

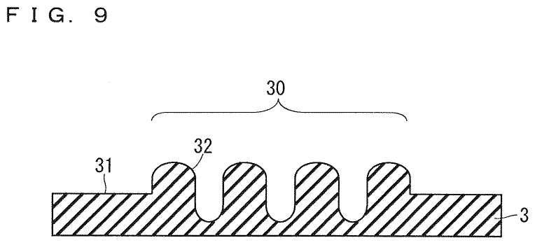

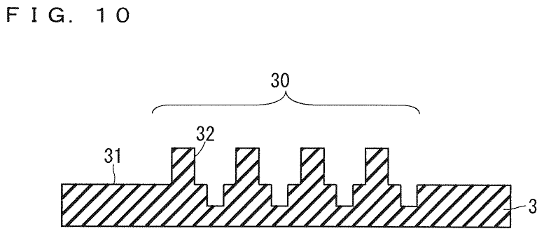

In FIGS. 4 to 6, the cross-sectional shape of the non-reference planes 32 of the second insulating layer 3 are rectangular. However, the cross-sectional shape of the non-reference planes 32 may be triangular as illustrated in FIG. 7 or tapered as illustrated in FIG. 8. Further, as illustrated in FIG. 9, the non-reference planes 32 may be a curved surface. In FIG. 9, the non-reference plane 32 is formed from both a convex portion and a concave portion with respect to the reference plane 31. FIG. 10 illustrates an example in which the non-reference plane 32 is formed from both a convex-portion and a concave portion with respect to the reference plane 31, and the convex portion or the concave portion forming the non-reference plane 32 is rectangular in cross-sectional view.

### <B-3. Non-Reference Plane Arrangement Pattern>

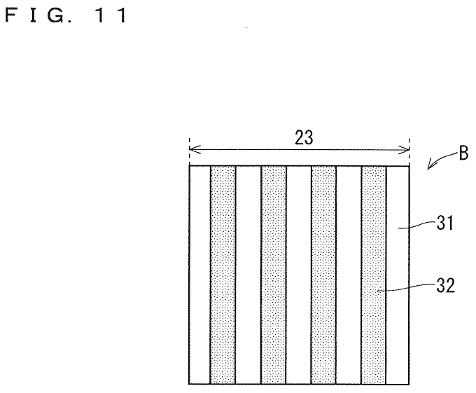

The concave-convex region 30 includes the reference plane 31 and the non-reference planes 32. In the concave-convex region 30, the non-reference planes 32 can be arranged in various patterns. In FIG. 3, part of the concave-convex region 30 is illustrated as a region B. FIG. 11 is an enlarged view of the region B in FIG. 3. In FIG. 11, the non-reference planes 32 are arranged in a striped pattern. Here, a thickness, a length, the number, and the interval of the stripe pattern are not limited to those illustrated in the drawing.

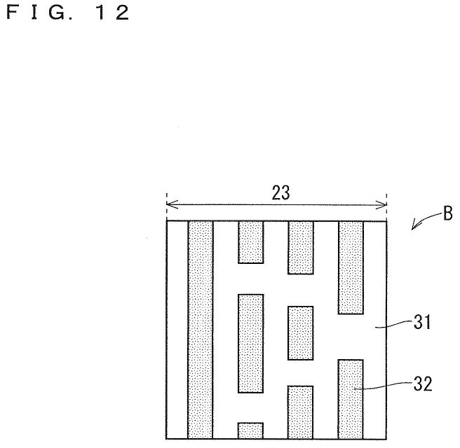

As illustrated in FIG. 12, the non-reference planes 32 may be arranged in a so-called incomplete stripe pattern, which partially omits the stripe pattern of FIG. 11. In FIG. 12, among the four patterns on the non-reference planes 32, the three patterns excluding the leftmost pattern are not completely continuous patterns in the vertical direction of the drawing, and are interrupted at at least one place. These omitted portions of the patterns of the non-reference planes 32 are not limited to those illustrated in FIG. 12.

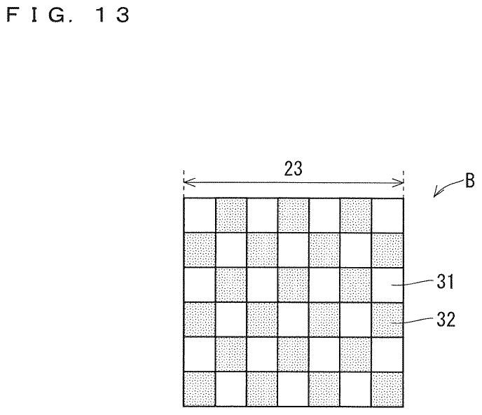

As illustrated in FIG. 13, the non-reference planes 32 may be arranged in a rectangular dot pattern. The dimensions of the dots or the positional relationship between adjacent patterns are not limited to those illustrated in FIG. 13. In FIG. 13, the patterns of the adjacent non-reference planes 32 are in contact with each other, and the reference plane 31 is surrounded by four patterns of the non-reference planes 32. The patterns of the adjacent non-reference planes 32 do not necessarily need be in contact with each other. Further, the shape of the dot pattern is not limited to a rectangle, but may be a polygon.

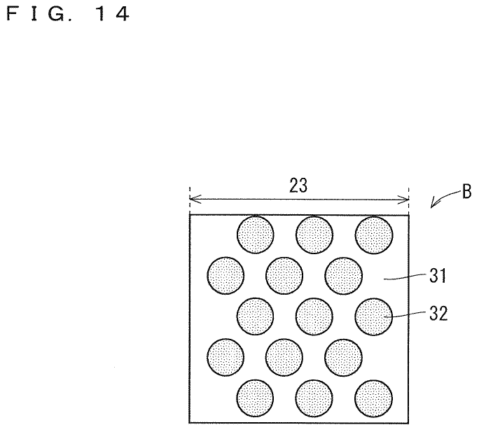

As illustrated in FIG. 14, the non-reference planes 32 may be arranged in a circular dot pattern. Further, an elliptical dot pattern may be adopted instead of the circular dot pattern. The dimensions of the dots or the positional relationship between adjacent patterns are not limited to those illustrated in FIG. 14. In FIG. 14, the patterns of adjacent non-reference planes 32 are not in contact with each other, but they may be in contact with each other.

### <B-4. Arrangement of Concave-Convex Region>

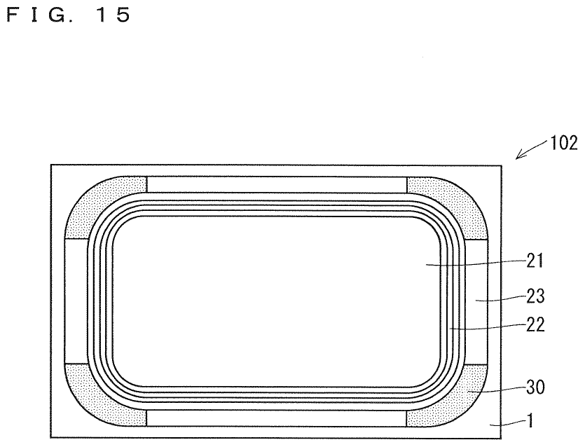

In FIG. 3, the concave-convex region 30 exists over the entire second termination region 23 so as to surround the first termination region 22. However, the concave-convex region 30 may be provided only in a part of the second termination region 23. For example, as illustrated in FIG. 15, the concave-convex region 30 may be provided only at the corner portions of the semiconductor device 102 in the second termination region 23. With the concave-convex regions 30 provided in the corner portions where a high electric field is prone to occur, a break or an increase in leakage current caused by the THB test is effectively suppressed and delayed. Note that the concave-convex region 30 may be provided at any location other than the corner portions that are locations where a high electric field is prone to occur.

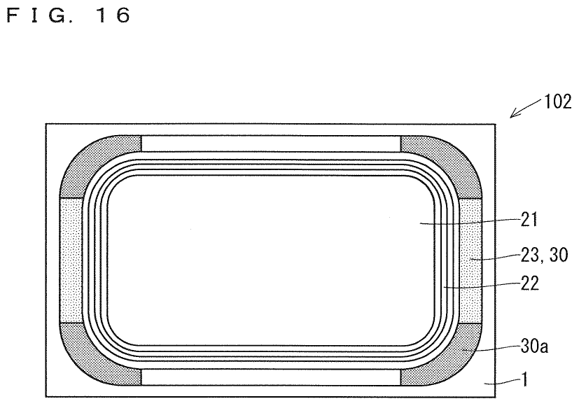

As illustrated in FIG. 16, the concave-convex regions 30 may be arranged in the entire second termination region 23, and then the corner portions may be formed into high-density concave-convex regions 30a where the density of the concave-convex pattern is higher than that of the other concave-convex regions 30. Note that the high-density concave-convex region 30a may be provided at any location other than the corner portions that are locations where a high electric field is prone to occur.

### <B-5. Manufacturing Process>

The processes of forming the second insulating layer 3 having the non-reference planes 32 formed by the convex portions with respect to the reference plane 31 and the periphery thereof illustrated in FIG. 4 will be described below.

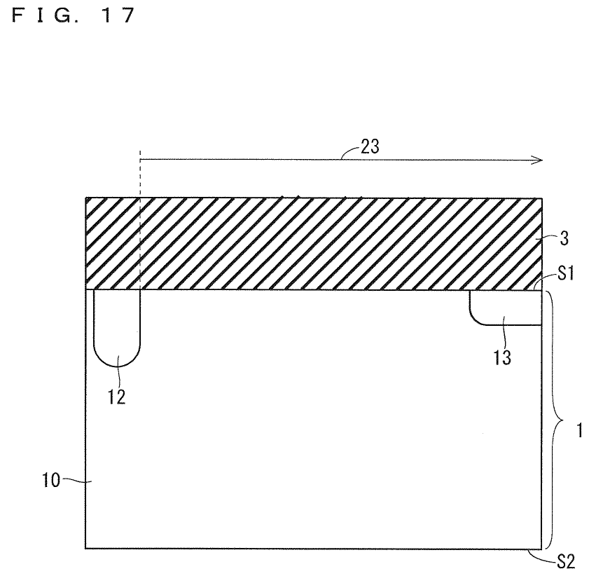

First, as illustrated in FIG. 17, the first termination semiconductor layer 12 and the second termination semiconductor layer 13 are formed in the front surface layer of the first main surface S1 of the semiconductor substrate 1 having the drift layer 10. Then, the second insulating layer 3 is formed on the first main surface S1 of the semiconductor substrate 1. Note that the second insulating layer 3 may be formed before the first termination semiconductor layer 12 and the second termination semiconductor layer 13 are formed.

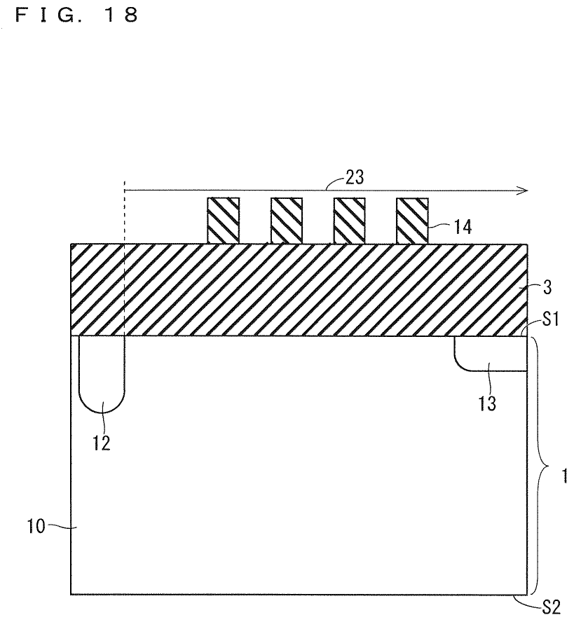

Next, as illustrated in FIG. 18, a resist film 14 having arbitrary openings is formed on the second insulating layer 3. Note that when forming the second insulating layer 3 having the non-reference planes 32 formed as concave portions with respect to the reference plane 31, the pattern of the resist film 14 illustrated in FIG. 18 may be reversed.

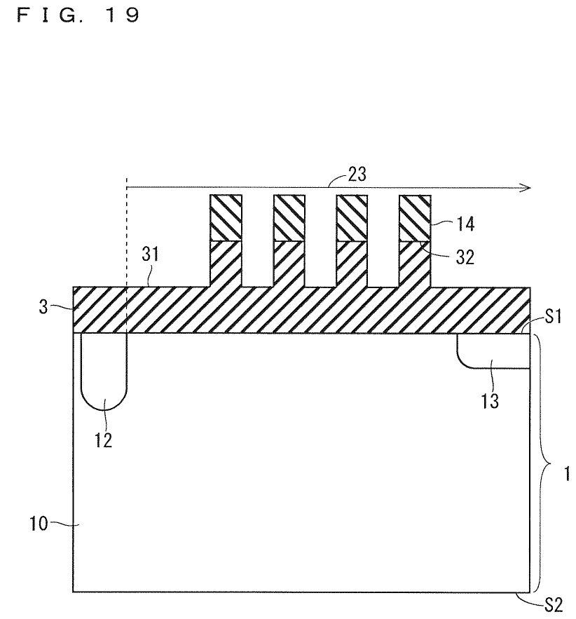

Thereafter, as illustrated in FIG. 19, only a portion of the thickness of the second insulating layer 3 within the openings of the resist film 14 is removed. At this point, the second insulating layer 3 within the openings of the resist film 14 needs to have a thickness sufficient to maintain insulation from the semiconductor substrate 1. The process is a typical half-etch or etch-back process, and may be wet or dry. Through this process, the upper surface of the second insulating layer 3 at the openings of the resist film 14 turns into the reference plane 31, and the upper surface of the second insulating layer 3 directly under the resist film 14 turns into the non-reference planes 32.

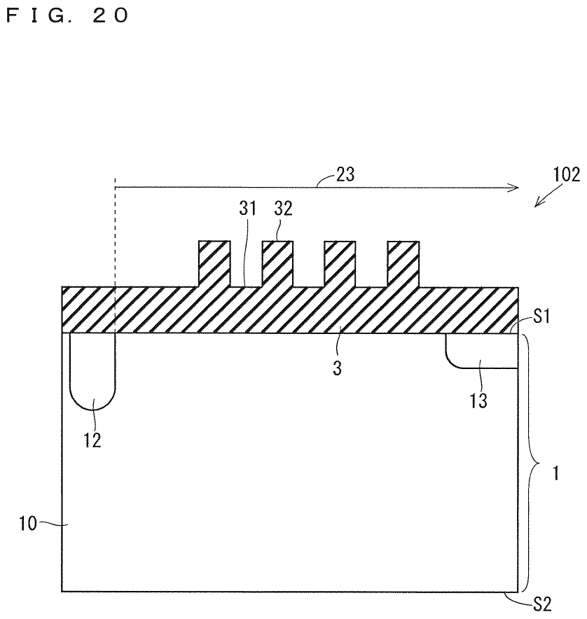

Next, by removing the resist film 14, the configuration illustrated in FIG. 20 is obtained.

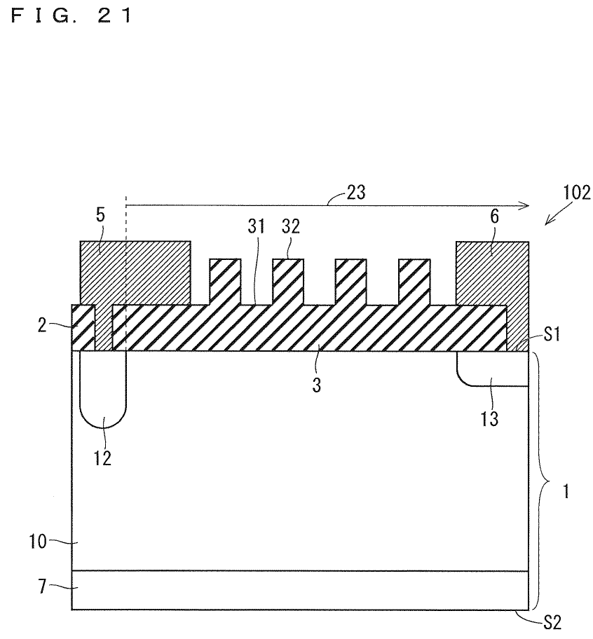

Thereafter, the configuration illustrated in FIG. 21 is obtained by forming the first termination electrode layer 5 and the second termination electrode layer 6, respectively.

The above flow is the simplest method for forming a concave-convex shape on the upper surface of the second insulating layer 3. Alternatively, the concave-convex shape of the second insulating layer 3 can be formed using a LOCal Oxidation of Silicon (LOCOS) flow, although the number of steps increases. In addition, the concave-convex shape of the second insulating layer 3 can be formed in a simple manner by a deposition process to form a rough surface on the second insulating layer 3 or by a process to roughen the second insulating layer 3 previously made flat by etching, although a deep concave-convex shape cannot be obtained.

### <B-6. Effect>

In the semiconductor device 102 according to Embodiment 2, the upper surface of the second insulating layer 3 has a concave-convex region 30 being a concave-convex shape in cross-sectional view. Therefore, according to the semiconductor device 102, the following effects are obtained in addition to the effects of the semiconductor device 101 according to Embodiment 1. That is, with the upper surface of the second insulating layer 3 having a concave-convex shape, the molten material corroded and ionized at the outermost first termination electrode layer 5 or the second termination electrode layer 6 due to the test load during the THB test moves a longer distance between the outermost first termination electrode layer 5 and the second termination electrode layer 6 by voltage bias. This enables to suppress and delay a break or an increase in leakage current caused by the THB test.

### C. Embodiment 3

### <C-1. Configuration>

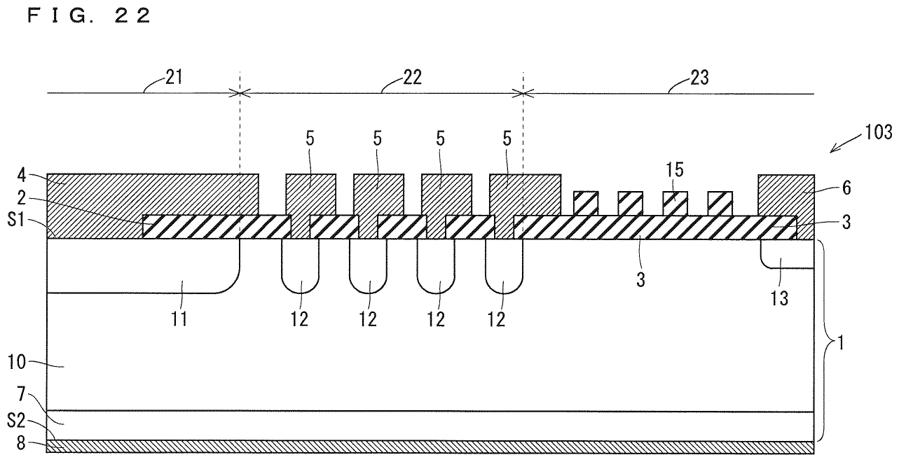

The top view of the semiconductor device 103 according to Embodiment 3 is the same as the semiconductor device 102 according to Embodiment 2, as illustrated in FIG. 3. FIG. 22 is a cross-sectional view of the semiconductor device 103 taken along line A-A′ in FIG. 3. The semiconductor device 103 differs from the semiconductor device 102 according to Embodiment 2 in that a plurality of third insulating layers 15 are formed discretely on the flat upper surface of second insulating layer 3. That is, in the semiconductor device 103, the flat upper surface of the second insulating layer 3 and the plurality of third insulating layers 15 form a concave-convex shape. Although the plurality of third insulating layers 15 are adopted here, another insulating layer may be provided on the flat upper surface of the second insulating layer 3 and separated from the third insulating layers 15. Also, another insulating layer may be provided in any number of layers on and in contact with the third insulating layers 15. The number of types of insulating layers to be used can be determined by comparing and considering the advantages of improving withstand voltage in the THB test and the disadvantages of increasing the number of processes.

### <C-2. Effect>

In the semiconductor device 103 according to Embodiment 3, the upper surface of the second insulating layer 3 is flat, and the plurality of third insulating layers are discretely provided on the upper surface of the second insulating layer 3. With this configuration, the upper surface of the second insulating layer 3 and the third insulating layers form a concave-convex shape, so that the same effects can be obtained as the semiconductor device 102 according to Embodiment 2 in which the upper surface of the second insulating layer 3 has a concave-convex shape.

### D. Embodiment 4

### <D-1. Configuration>

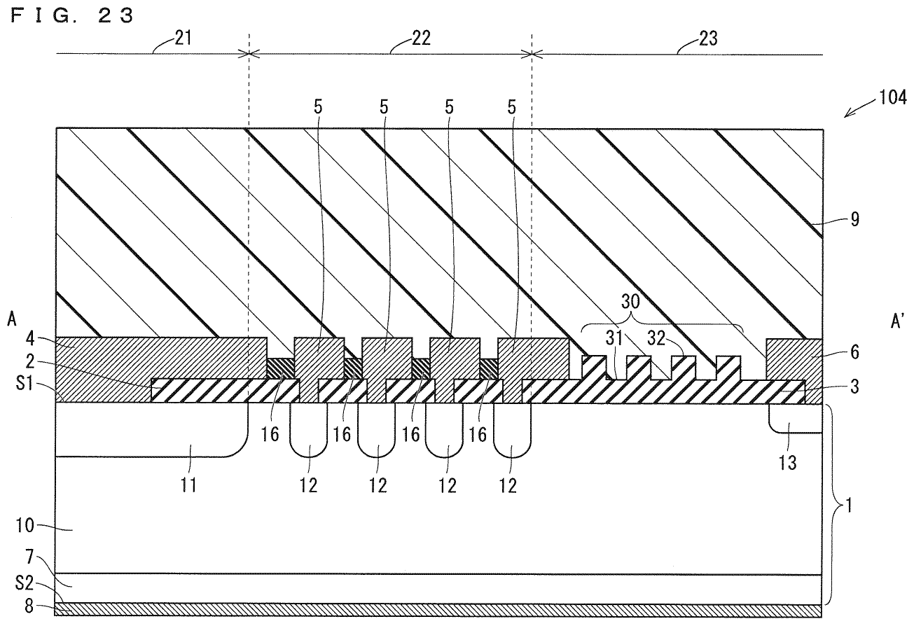

The top view of a semiconductor device 104 according to Embodiment 4 is the same as the semiconductor device 102 according to Embodiment 2, as illustrated in FIG. 3. FIG. 23 is a cross-sectional view of the semiconductor device 104 taken along line A-A′ in FIG. 3. The semiconductor device 104 differs from the semiconductor device 102 according to Embodiment 2 in that the first insulating layer 2 has convex portions 16 on the upper surface between the active region electrode layer 4 and the first termination electrode layer 5, and between the adjacent first termination electrode layers 5. The number of convex portions 16 on the first insulating layer 2 is not limited to that illustrated in FIG. 23. The convex portions 16 are not necessarily provided all of between the active region electrode layer 4 and the first termination electrode layer 5, and between the adjacent first termination electrode layers 5.

### <D-2. Effect>

In the semiconductor device 104 according to Embodiment 4, the semiconductor substrate 1 includes an active region semiconductor layer 11 of the first conductivity type provided in the front surface layer of the drift layer 10 on the first main surface S1 side in the active region 21. The semiconductor device 104 includes the active region electrode layer 4 provided on the first main surface S1 and electrically connected to the active region semiconductor layer 11. The upper surface of the first insulating layer 2 has the convex portions 16 at least between the active region electrode layer 4 and the first termination electrode layer 5, and between the adjacent first termination electrode layers 5. According to the above configuration, the distance between the active region electrode layer 4 and the first termination electrode layer 5 or the distance between the first termination electrode layers 5 can be defined by the width of the convex portion 16 of the first insulating layer 2. The distance is significant design parameters for maintaining breakdown voltage. The shorter these distances, the faster the corrosive materials move. However, with the upper surface of the second insulating layer 3 having a concave-convex shape, the THB resistance can be maintained or improved. Therefore, in the first termination region 22, dimensions can be designed freely with a focus on the breakdown voltage.

Although preferred Embodiments have been described above in detail, they are not limited to above Embodiments, and various modifications and substitutions may be made to above Embodiments without departing from the scope of the claims.

Hereinafter, the aspects of the present disclosure will be collectively described as Appendices.

### Appendix 1

A semiconductor device being divided into an active region, a first termination region surrounding the active region, and a second termination region surrounding the first termination region in a plan view, the semiconductor device comprising
a semiconductor substrate having a first main surface and a second main surface that is a main surface opposite to the first main surface, wherein
the semiconductor substrate includes
   a drift layer of a second conductivity type,
   a plurality of first termination semiconductor layers of a first conductivity type provided in a front surface layer of the drift layer on the first main surface side in the first termination region, and
   a second termination semiconductor layer of the second conductivity type provided in the surface layer of the drift layer on the first main surface side at an end portion of the semiconductor substrate in the second termination region, the semiconductor device further comprising:
a first insulating layer provided on the first main surface in the first termination region;
a plurality of first termination electrode layers provided on the first main surface and electrically connected to the plurality of first termination semiconductor layers through openings of the first insulating layer;
a second termination electrode layer provided on the first main surface and electrically connected to the second termination semiconductor layer;
a second insulating layer provided on the first main surface, having one end thereof in contact with outermost one of the plurality of first termination semiconductor layers among the plurality of first termination semiconductor layers, and having an other end thereof in contact with the second termination semiconductor layer; and
a sealing material in direct contact with un upper surface of the second insulating layer.

### Appendix 2

The semiconductor device according to Appendix 1, wherein
the upper surface of the second insulating layer has a concave-convex region being a concave-convex shape in cross-sectional view.

### Appendix 3

The semiconductor device according to Appendix 2, wherein
the concave-convex region includes a reference plane having a same height as an upper surface of the first insulating layer, and non-reference planes formed as convex portions protruding from the reference plane.

### Appendix 4

The semiconductor device according to Appendix 2, wherein
the concave-convex region includes a reference plane having a same height as an upper surface of the first insulating layer, and non-reference planes formed as concave portions depressed from the reference plane.

### Appendix 5

The semiconductor device according to Appendix 3, wherein
the convex portions located at both ends of the second insulating layer are under outermost one of the plurality of first termination electrode layers among the plurality of first termination electrode layers and the second termination electrode layer.

### Appendix 6

The semiconductor device according to any one of Appendices 3 to 5, wherein
the non-reference planes are rectangular in cross-sectional view.

### Appendix 7

The semiconductor device according to any one of Appendices 3 to 5, wherein
the non-reference planes are triangular in cross-sectional view.

### Appendix 8

The semiconductor device according to any one of Appendices 3 to 5, wherein
the non-reference planes are tapered in cross-sectional view.

### Appendix 9

The semiconductor device according to any one of Appendices 3 to 5, wherein
the non-reference planes are curved surface in cross-sectional view.

### Appendix 10

The semiconductor device according to any one of Appendices 3 to 9, wherein
the non-reference planes are arranged in a striped pattern.

### Appendix 11

The semiconductor device according to any one of Appendices 3 to 9, wherein
the non-reference planes are arranged in an incomplete striped pattern.

### Appendix 12

The semiconductor device according to any one of Appendices 3 to 9, wherein
the non-reference planes are arranged in a polygonal dot pattern.

### Appendix 13

The semiconductor device according to any one of Appendices 3 to 9, wherein
the non-reference planes are arranged in a circular or elliptical dot pattern.

### Appendix 14

The semiconductor device according to any one of Appendices 2 to 13, wherein
the concave-convex region is provided only at a corner portion of the second termination region.

### Appendix 15

The semiconductor device according to any one of Appendices 2 to 13, wherein
the concave-convex region is provided over the entire second termination region, and
the concave-convex regions provided at the corner portion of the second termination region is a high-density concave-convex region in which a density of its concave-convex pattern is higher than that of an other concave-convex regions.

### Appendix 16

The semiconductor device according to Appendix 1, wherein
an upper surface of the second insulating layer is flat, and
a plurality of third insulating layers are discretely provided on the upper surface of the second insulating layer.

### Appendix 17

The semiconductor device according to any one of Appendices 1 to 16, wherein
the semiconductor substrate includes an active region semiconductor layer of the first conductivity type provided in the front surface layer of the drift layer on the first main surface side in the active region, the semiconductor device further comprising
an active region electrode layer provided on the first main surface and electrically connected to the active region semiconductor layer, wherein
an upper surface of the first insulating layer has convex portions at least between the active region electrode layer and the first termination electrode layer, and between the adjacent first termination electrode layers.

### Appendix 18

A method of manufacturing a semiconductor device being divided into an active region, a first termination region surrounding the active region, and a second termination region surrounding the first termination region in a plan view, the method of manufacturing comprising:
preparing a semiconductor substrate having a drift layer of a second conductivity type and having a first main surface and a second main surface that is a main surface opposite to the first main surface;
forming a plurality of first termination semiconductor layers of a first conductivity type provided in a front surface layer of the drift layer on the first main surface side in the first termination region;
forming a second termination semiconductor layer of a second conductivity type provided in the surface layer of the drift layer on the first main surface side at an end portion of the semiconductor substrate in the second termination region:
forming a first insulating layer provided on the first main surface in the first termination region;
forming a plurality of first termination electrode layers provided on the first main surface and electrically connected to the plurality of first termination semiconductor layers through openings of the first insulating layer;
forming a second termination electrode layer provided on the first main surface and electrically connected to the second termination semiconductor layer;
forming a second insulating layer provided on the first main surface, having one end thereof in contact with outermost one of the plurality of first termination semiconductor layers among the plurality of first termination semiconductor layers, and having an other end thereof in contact with the second termination semiconductor layer; and
sealing un upper surface of the second insulating layer with a sealing material.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor device being divided into an active region, a first termination region surrounding the active region, and a second termination region surrounding the first termination region in a plan view, the semiconductor device comprising
a semiconductor substrate having a first main surface and a second main surface that is a main surface opposite to the first main surface, wherein
the semiconductor substrate includes
a drift layer of a second conductivity type,
a plurality of first termination semiconductor layers of a first conductivity type provided in a front surface layer of the drift layer on the first main surface side in the first termination region, and
a second termination semiconductor layer of the second conductivity type provided in the surface layer of the drift layer on the first main surface side at an end portion of the semiconductor substrate in the second termination region, the semiconductor device further comprising:
a first insulating layer provided on the first main surface in the first termination region;
a plurality of first termination electrode layers provided on the first main surface and electrically connected to the plurality of first termination semiconductor layers through openings of the first insulating layer;
a second termination electrode layer provided on the first main surface and electrically connected to the second termination semiconductor layer;
a second insulating layer provided on the first main surface, having one end thereof in contact with outermost one of the plurality of first termination semiconductor layers among the plurality of first termination semiconductor layers, and having an other end thereof in contact with the second termination semiconductor layer; and
a sealing material in direct contact with un upper surface of the second insulating layer.

2. The semiconductor device according to claim 1, wherein
the upper surface of the second insulating layer has a concave-convex region being a concave-convex shape in cross-sectional view.

3. The semiconductor device according to claim 2, wherein
the concave-convex region includes a reference plane having a same height as an upper surface of the first insulating layer, and non-reference planes formed as convex portions protruding from the reference plane.

4. The semiconductor device according to claim 2, wherein
the concave-convex region includes a reference plane having a same height as an upper surface of the first insulating layer, and non-reference planes formed as concave portions depressed from the reference plane.

5. The semiconductor device according to claim 3, wherein
the convex portions located at both ends of the second insulating layer are under outermost one of the plurality of first termination electrode layers among the plurality of first termination electrode layers and the second termination electrode layer.

6. The semiconductor device according to claim 3, wherein
the non-reference planes are rectangular in cross-sectional view.

7. The semiconductor device according to claim 3, wherein
the non-reference planes are triangular in cross-sectional view.

8. The semiconductor device according to claim 3, wherein
the non-reference planes are tapered in cross-sectional view.

9. The semiconductor device according to claim 3, wherein
the non-reference planes are curved surface in cross-sectional view.

10. The semiconductor device according to claim 3, wherein
the non-reference planes are arranged in a striped pattern.

11. The semiconductor device according to claim 3, wherein
the non-reference planes are arranged in an incomplete striped pattern.

12. The semiconductor device according to claim 3, wherein
the non-reference planes are arranged in a polygonal dot pattern.

13. The semiconductor device according to claim 3, wherein
the non-reference planes are arranged in a circular or elliptical dot pattern.

14. The semiconductor device according to claim 2, wherein
the concave-convex region is provided only at a corner portion of the second termination region.

15. The semiconductor device according to claim 2, wherein
the concave-convex region is provided over the entire second termination region, and
the concave-convex regions provided at the corner portion of the second termination region is a high-density concave-convex region in which a density of its concave-convex pattern is higher than that of an other concave-convex regions.

16. The semiconductor device according to claim 1, wherein
an upper surface of the second insulating layer is flat, and
a plurality of third insulating layers are discretely provided on the upper surface of the second insulating layer.

17. The semiconductor device according to claim 1, wherein
the semiconductor substrate includes an active region semiconductor layer of the first conductivity type provided in the front surface layer of the drift layer on the first main surface side in the active region, the semiconductor device further comprising
an active region electrode layer provided on the first main surface and electrically connected to the active region semiconductor layer, wherein
an upper surface of the first insulating layer has convex portions at least between the active region electrode layer and the first termination electrode layer, and between the adjacent first termination electrode layers.

18. A method of manufacturing a semiconductor device being divided into an active region, a first termination region surrounding the active region, and a second termination region surrounding the first termination region in a plan view, the method of manufacturing comprising:
preparing a semiconductor substrate having a drift layer of a second conductivity type and having a first main surface and a second main surface that is a main surface opposite to the first main surface;
forming a plurality of first termination semiconductor layers of a first conductivity type provided in a front surface layer of the drift layer on the first main surface side in the first termination region;
forming a second termination semiconductor layer of a second conductivity type provided in the surface layer of the drift layer on the first main surface side at an end portion of the semiconductor substrate in the second termination region:
forming a first insulating layer provided on the first main surface in the first termination region;
forming a plurality of first termination electrode layers provided on the first main surface and electrically connected to the plurality of first termination semiconductor layers through openings of the first insulating layer;
forming a second termination electrode layer provided on the first main surface and electrically connected to the second termination semiconductor layer;
forming a second insulating layer provided on the first main surface, having one end thereof in contact with outermost one of the plurality of first termination semiconductor layers among the plurality of first termination semiconductor layers, and having an other end thereof in contact with the second termination semiconductor layer; and
sealing un upper surface of the second insulating layer with a sealing material.
